(19) United States
(12) Patent Application Publication
(10) Pub. No.: US 2021/0320198 A1
(43) Pub. Date: Oct. 14, 2021

(54) TRANSISTOR

(71) Applicant: National Tsing Hua University, Hsinchu City (TW)

(72) Inventors: Meng-Chyi WU, Hsinchu City (TW); Chia-Jui YU, Hsinchu City (TW); Chin-Wei HSU, Hsinchu City (TW)

(73) Assignee: National Tsing Hua University, Hsinchu City (TW)

(21) Appl. No.: 16/922,416

(22) Filed: Jul. 7, 2020

(30) Foreign Application Priority Data
Apr. 8, 2020 (TW) 109111722

(51) Int. Cl. H01L 29/778; H01L 29/20; H01L 29/423; H01L 29/06

(52) U.S. Cl. CPC H01L 29/7786; H01L 29/0649; H01L 29/4232; H01L 29/2003

(57) ABSTRACT

A transistor includes a substrate, a semiconductor unit disposed on the substrate, a gate unit, a source electrode and a drain electrode. The gate unit includes a non-metal gate part disposed on the semiconductor unit, and a metal gate layer entirely enclosing the non-metal gate part. The drain and source electrodes are disposed respectively on two opposite sides of the gate unit.

### CROSS-REFERENCE TO RELATED APPLICATION

This application claims priority of Taiwanese Patent Application No. 109111722, filed on Apr. 8, 2020.

### FIELD

The disclosure relates to a transistor, and more particularly to a transistor including a metal gate layer enclosing a non-metal gate part.

### BACKGROUND

Recently, power semiconductor devices have gained widespread applications and demands. High electron mobility transistors (HEMTs) made of materials such as GaN have gained popularity due to their switch properties and resistance to electrical breakdown.

There are typically two types of GaN-HEMTs: depletion type and enhancement type. The depletion type GaN-HEMTs are generally considered to be superior over the enhancement type GaN-HEMTs. However, since current flow exists at the state of no bias, the depletion type GaN-HEMTs has the disadvantages of increased power consumption and poor safeness. Therefore, the current trend is toward improvements of the enhancement type GaN-HEMTs.

It is known that a metal-insulator-semiconductor (MIS) gate structure can provide improved transistor characteristics compared to a metal-semiconductor gate structure, such as schottky gate structure. Therefore, development of metal-insulator-semiconductor HEMTs (MIS-HEMT) has become a mainstream technique to suppress the gate current.

FIG. 1 shows a conventional enhancement type transistor 1 having a metal-insulation-semiconductor (MIS) gate structure 12, in which a gate metal 11 is connected only to a top surface 10 of a lower gate part. However, this transistor is prone to current leakage which greatly impairs transistor characteristics.

### SUMMARY

Therefore, an object of the present disclosure is to provide a transistor that can alleviate at least one of the drawbacks of the prior art.

According to this disclosure, a transistor includes a substrate, a semiconductor unit, a gate unit, a source electrode and a drain electrode. The semiconductor unit is disposed on the substrate. The gate unit includes a non-metal gate part that is disposed on the semiconductor unit, and a metal gate layer that entirely encloses the non-metal gate part. The drain and source electrodes are disposed respectively on two opposite sides of the gate unit.

### BRIEF DESCRIPTION OF THE DRAWINGS

Other features and advantages of the disclosure will become apparent in the following detailed description of the embodiment with reference to the accompanying drawings, of which:

FIG. 1 is a schematic view of a conventional enhancement type transistor;

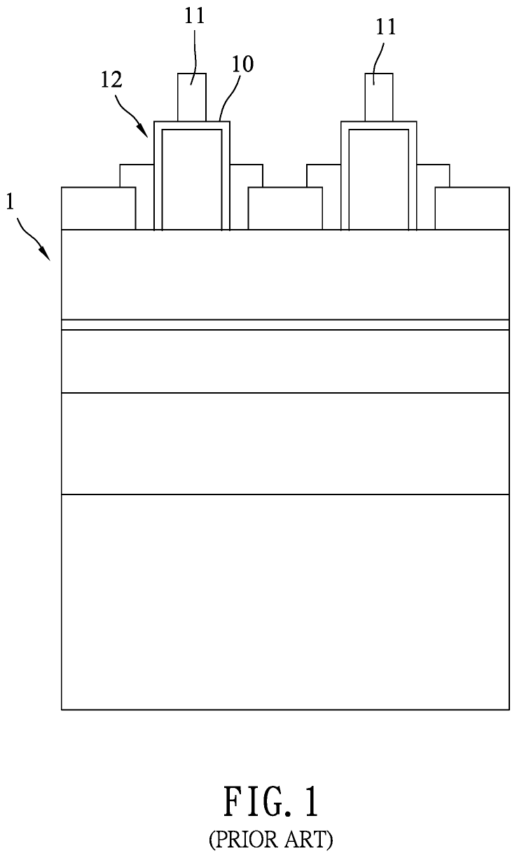

FIG. 2 is a schematic view of an embodiment of a transistor according to the present disclosure;

FIG. 3 is a diagram showing drain current density (J_{DS}) and transconductance (Gₘ) of the embodiment and the conventional enhancement type transistor, as a function of gate voltage (V_{GS});

FIG. 4 is a diagram showing the drain current density (J_{DS}) and the gate leakage current density (J_{GS}) of the embodiment and the conventional enhancement type transistor, as a function of the gate voltage (V_{GS});

FIG. 5 is a diagram showing the drain current density (J_{DS}) of the embodiment and the conventional enhancement type transistor, as a function of drain-to-source voltage (V_{DS}); and

FIG. 6 is a diagram showing gain of the embodiment and the conventional enhancement type transistor, as a function of frequency.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

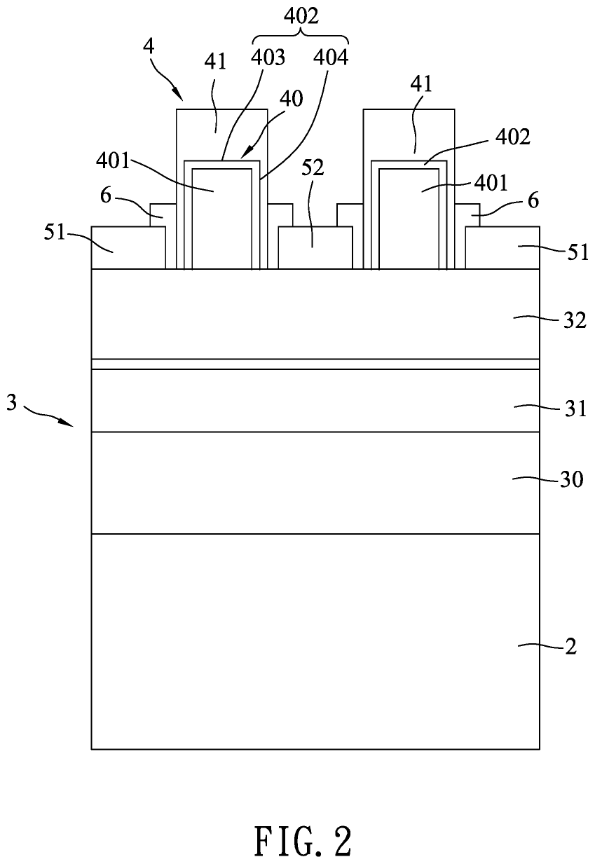

FIG. 2 shows an embodiment of a transistor according to the present disclosure. In this embodiment, the transistor is a HEMI, and includes a substrate 2, a semiconductor 3, a gate unit 4, a source electrode 51, a drain electrode 52 and an oxide layer 6.

The substrate 2 may be made of a semiconductor material, such as group IV semiconductor, IV-IV semiconductor, III-V semiconductor, etc. Alternatively, the substrate 2 may be made of an insulating material. In this embodiment, the substrate 2 is made of silicon.

The semiconductor unit 3 is disposed on the substrate 2, and includes a buffer layer 30 disposed on the substrate 2, a first epitaxial layer 31 disposed on the buffer layer 30, and a second epitaxial layer 32 disposed on the first epitaxial layer 31. The second epitaxial layer 32 has an energy gap larger than that of the first epitaxial layer 31. In this embodiment, the first epitaxial layer 31 is made of undoped GaN, and the second epitaxial layer 32 is made of AlGaN. The second epitaxial layer 32 maybe a slightly doped AlGaN.

The gate unit 4 includes a non-metal gate part 40 that is disposed on the semiconductor unit 3, and a metal gate layer 41 that entirely encloses the non-metal gate part 40. The non-metal gate part 40 includes a gate semiconductor layer 401 that is formed on top of the semiconductor unit 3, and a gate insulating layer 402 that entirely encloses the gate semiconductor layer 401. The metal gate layer 41 entirely encloses the gate insulating layer 402, and is connected to the second epitaxial layer 32 of the semiconductor unit 3.

In this embodiment, the gate semiconductor 401 of the non-metal gate part 40 is made of p-type GaN, the gate insulating layer 402 is made of a high dielectric material, such as Al₂O₃, and the metal gate layer 41 includes a nickel sub-layer and a gold sub-layer.

Specifically, the non-metal gate part 40 has a top non-metal surface 403, and a lateral non-metal surface 404 that interconnects between the top non-metal surface 403 and the second epitaxial layer 32 of the semiconductor unit 3.

The gate insulating layer 402 has the top and lateral non-metal surfaces 403, 404. The metal gate layer 41 entirely covers the top and lateral non-metal surfaces 403, 404, and is in contact with the second epitaxial layer 32 of the semiconductor unit 3.

For fabricating the gate unit 4, the gate insulating layer 402 may be formed using chemical vapor deposition with suitable photomask after the formation of the gate semiconductor layer 401, and the metal gate layer 41 may then be formed by physical vapor deposition.

The drain and source electrodes 51, 52 are disposed respectively on two opposite sides of the gate unit 4. The oxide layer 6 is disposed between and separates the source electrode 51 and the gate unit 4, and is disposed between and separates the gate unit 4 and the drain electrode 52.

Because the metal gate layer 41 fully encloses the non-metal gate part 40, it has lateral layer portions in addition to the top layer portion. Therefore, the gate control ability of the transistor can be increased from the level of two dimensional to the level of three dimensional. The gate leakage current can also be reduced. In addition, other transistor characteristics, such as transconductance, current gain, power gain, cut-off frequency and maximum oscillation frequency can be improved. Further, since the gate insulating layer 402 is made of a high dielectric constant material, the capacitance of the oxide layer of the transistor is increased, resulting in improved current and power outputs.

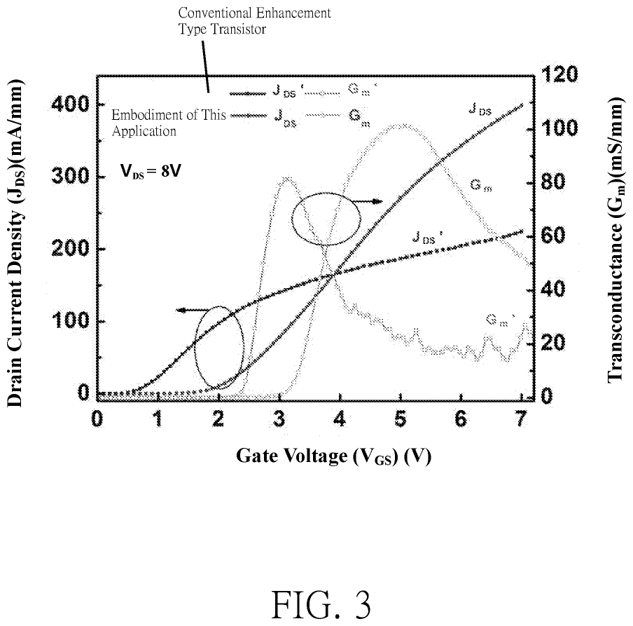

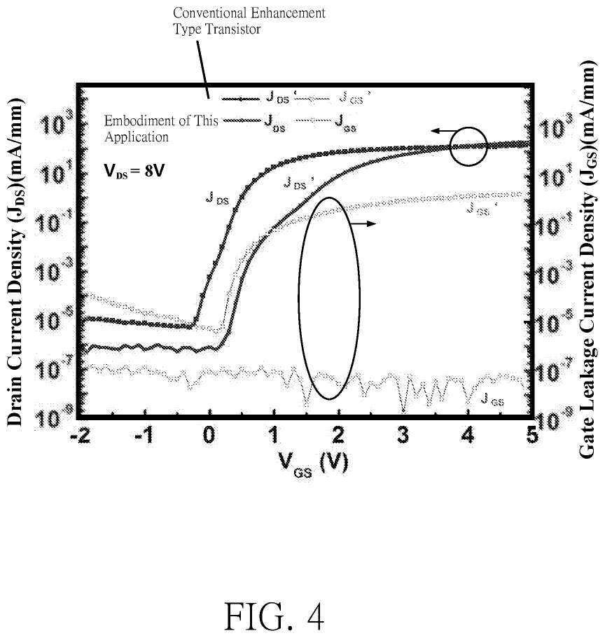

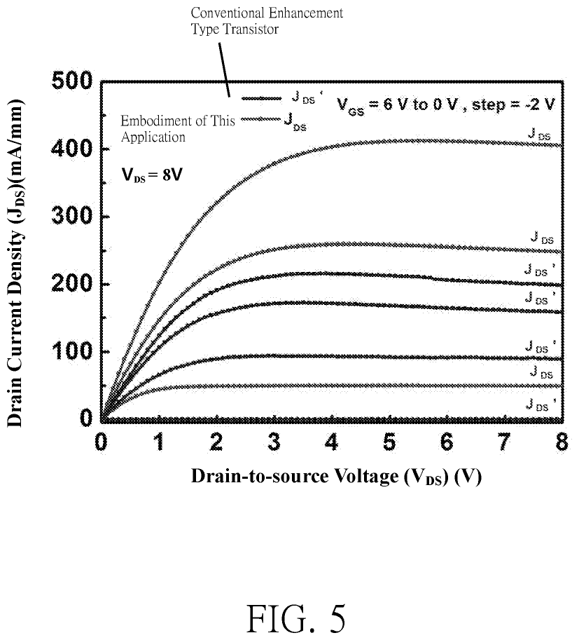

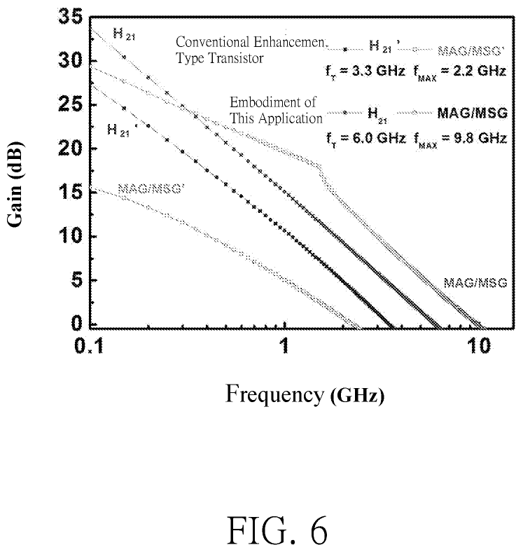

Referring to FIGS. 3 to 6, measurement and test results for the embodiment of the transistor according to this disclosure and the convention transistor are shown. For the embodiment of the disclosure, a threshold voltage is 1.5V (see FIG. 3). When the gate bias (V_{GS}) is 5V, the gate leakage current (J_{GS}) can be as low as 10⁻⁸ mA/mm (see FIG. 4). The maximum drain saturation current density (J_{DS}) of the transistor is 412.3 mA/mm when the on-resistance is 5 Ω-mm (see FIG. 5). The ratio of the drain current density (J_{DS}) to the gate leakage current density (J_{GS}) can be enhanced from 10² to 10¹⁰ (see FIG. 4). As shown in FIG. 6, the cut-off frequency (f_{T}) of the transistor can be as high as 6.0 GHz, and the maximum oscillation frequency (f_{MAX}) can be as high as 9.8 GHz. The abovementioned DC characteristics of the embodiment are better than those of the conventional enhancement type transistor.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiment but is intended to cover various arrangements included within the spirit and scope of the broadest interpretation so as to encompass all such modifications and equivalent arrangements.

What is claimed is:

1. A transistor comprising:
a substrate;
a semiconductor unit disposed on said substrate;
a gate unit including a non-metal gate part that is disposed on said semiconductor unit, and a metal gate layer that entirely encloses said non-metal gate part;
a source electrode; and
a drain electrode, said drain and source electrodes being disposed respectively on two opposite sides of said gate unit.

2. The transistor as claimed in claim 1, wherein:
said non-metal gate part includes a gate semiconductor layer that is formed on top of said semiconductor unit, and a gate insulating layer that entirely encloses said gate semiconductor layer; and
said metal gate layer encloses said gate insulating layer and is connected to said semiconductor unit.

3. The transistor as claimed in claim 1, wherein:
said semiconductor unit includes a buffer layer that is disposed on said substrate, a first epitaxial layer that is disposed on said buffer layer, and a second epitaxial layer that is disposed on said first epitaxial layer; and
said transistor further comprises an oxide layer that is disposed between and separates said source electrode and said gate unit, and disposed between and separates said gate unit and said drain electrode.

4. The transistor as claimed in claim 2, wherein:
said gate semiconductor layer is made of P-type gallium nitride;
said gate insulating layer is made of aluminum oxide; and
said metal gate layer includes a nickel sub-layer and a gold sub-layer.

5. The transistor as claimed in claim 3, wherein:
said first epitaxial layer is made of gallium nitride; and
said second epitaxial layer is made of aluminum gallium nitride.

6. The transistor as claimed in claim 1, wherein said non-metal gate part has a top non-metal surface, and a lateral non-metal surface that interconnects between said top non-metal surface and said semiconductor unit, said metal gate layer entirely enclosing said top and lateral non-metal surfaces and being in contact with said semiconductor unit.

7. The transistor as claimed in claim 6, wherein:
said non-metal gate part includes a gate semiconductor layer that is formed on top of said semiconductor unit, and a gate insulating layer that encloses said gate semiconductor layer; and
said gate insulating layer having said top non-metal surface and said lateral non-metal surfaces.
